(19) United States
(12) Patent Application Publication
(10) Pub. No.: US 2022/0301851 A1
(43) Pub. Date: Sep. 22, 2022

(54) METHOD OF MANUFACTURING SEMICONDUCTOR DEVICE, SUBSTRATE PROCESSING METHOD, RECORDING MEDIUM, AND SUBSTRATE PROCESSING APPARATUS

(71) Applicant: Kokusai Electric Corporation, Tokyo (JP)

(72) Inventors: Takafumi NITTA, Toyama-shi (JP); Kiyohisa ISHIBASHI, Toyama-shi (JP); Tsukasa KAMAKURA, Toyama-shi (JP)

(73) Assignee: Kokusai Electric Corporation, Tokyo (JP)

(21) Appl. No.: 17/576,110

(22) Filed: Jan. 14, 2022

(30) Foreign Application Priority Data
Mar. 17, 2021 (JP) 2021-043042

(51) Int. Cl. H01L 21/02; C23C 16/52; C23C 16/30

(52) U.S. Cl. CPC H01L 21/0214; H01L 21/02211; H01L 21/02326; C23C 16/52; C23C 16/308

(57) ABSTRACT

A method of manufacturing a semiconductor device includes: (a) forming a nitride film containing a predetermined element on a substrate by performing a cycle a predetermined number of times, the cycle including sequentially performing: (a-1) supplying a first precursor gas containing the predetermined element to the substrate; (a-2) supplying a second precursor gas containing the predetermined element and having a thermal decomposition temperature lower than a thermal decomposition temperature of the first precursor gas to the substrate; and (a-3) supplying a nitriding gas to the substrate; and (b) oxidizing the nitride film formed in (a) and modifying the nitride film into an oxide film containing the predetermined element by supplying an oxidizing gas to the substrate.

### CROSS-REFERENCE TO RELATED APPLICATION

This application is based upon and claims the benefit of priority from Japanese Patent Application No. 2021-043042, filed on Mar. 17, 2021, the entire contents of which are incorporated herein by reference.

### TECHNICAL FIELD

The present disclosure relates to a method of manufacturing a semiconductor device, a substrate processing method, a recording medium, and a substrate processing apparatus.

### BACKGROUND

As a process of manufacturing a semiconductor device, a process of forming a film on a substrate is performed.

### SUMMARY

Some embodiments of the present disclosure provide a technique capable of improving the characteristics of a film formed on a substrate.

According to one embodiment of the present disclosure, there is provided a technique that includes: (a) forming a nitride film containing a predetermined element on a substrate by performing a cycle a predetermined number of times, the cycle including sequentially performing: (a-1) supplying a first precursor gas containing the predetermined element to the substrate; (a-2) supplying a second precursor gas containing the predetermined element and having a thermal decomposition temperature lower than a thermal decomposition temperature of the first precursor gas to the substrate; and (a-3) supplying a nitriding gas to the substrate; and (b) oxidizing the nitride film formed in (a) and modifying the nitride film into an oxide film containing the predetermined element by supplying an oxidizing gas to the substrate.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus suitably used in some embodiments of the present disclosure, in which the portion of the process furnace 202 is illustrated in a vertical sectional view.

FIG. 2 is a schematic configuration diagram of the vertical process furnace of the substrate processing apparatus suitably used in some embodiments of the present disclosure, in which the portion of the process furnace 202 is illustrated in a sectional view taken along line A-A in FIG. 1.

FIG. 3 is a schematic configuration diagram of a controller 121 of the substrate processing apparatus suitably used in some embodiments of the present disclosure, in which a control system of the controller 121 is illustrated in a block diagram.

FIG. 4 is a diagram showing a flow in a substrate processing process according to some embodiments of the present disclosure.

FIG. 5A is a schematic diagram showing a state of a surface of a wafer 200 after a first precursor gas is supplied by performing step a1, FIG. 5B is a schematic view showing a state of the surface of the wafer 200 after a second precursor gas is supplied by performing step a2 after step a1 is performed, and FIG. 5C is a schematic view showing a state of the surface of the wafer 200 after a nitriding gas is supplied by performing step a3 after step a2 is performed.

FIG. 6 is a diagram showing an evaluation result of a film formed on a substrate.

FIG. 7 is a diagram showing an evaluation result of a film formed on a substrate.

FIG. 8 is a diagram showing an evaluation result of a film formed on a substrate.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### One or More Embodiments of the Present Disclosure

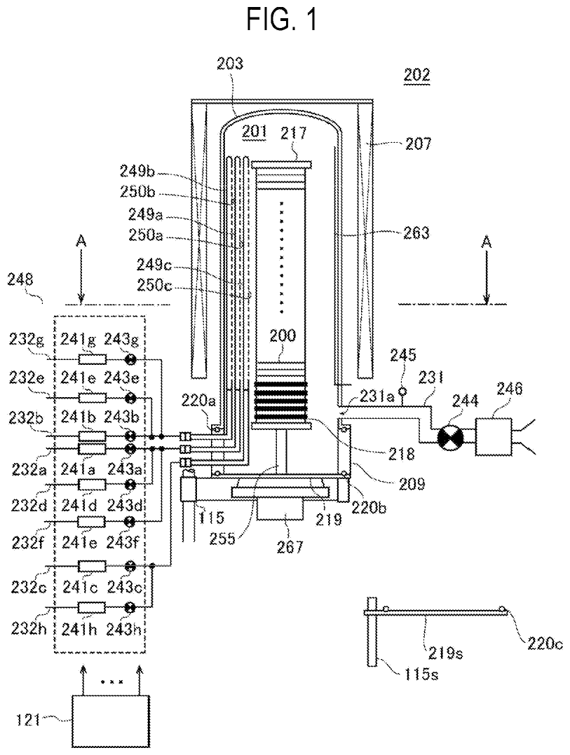

Hereinafter, an aspect of the present disclosure will be described mainly with reference to FIGS. 1 to 5. The drawings used in the following description are all schematic. The dimensional relationship of each element on the drawings, the ratio of each element, and the like do not always match the actual ones. Further, even between the drawings, the dimensional relationship of each element, the ratio of each element, and the like do not always match.

### (1) Configuration of Substrate Processing Apparatus

As shown in FIG. 1, a process furnace 202 includes a heater 207 as a temperature adjuster (heating part). The heater 207 has a cylindrical shape and is vertically installed by being supported by a holding plate. The heater 207 also functions as an activation mechanism (excitation part) that activates (excites) a gas with heat.

Inside the heater 207, a reaction tube 203 is arranged concentrically with the heater 207. The reaction tube 203 is made of a heat-resistant material such as, for example, quartz (SiO₂) or silicon carbide (SiC) and is formed in a cylindrical shape with an upper end thereof closed and a lower end thereof opened. Below the reaction tube 203, a manifold 209 is arranged concentrically with the reaction tube 203. The manifold 209 is made of a metallic material such as stainless steel (SUS) or the like and is formed in a cylindrical shape with upper and lower ends thereof opened. The upper end of the manifold 209 is engaged with the lower end of the reaction tube 203 and is configured to support the reaction tube 203. An O-ring 220a as a seal member is provided between the manifold 209 and the reaction tube 203. The reaction tube 203 is vertically installed similar to the heater 207. A process container (reaction container) is mainly composed of the reaction tube 203 and the manifold 209. A process chamber 201 is formed in the hollow portion of the process container. The process chamber 201 is configured to capable of accommodating wafers 200 as substrates. The wafers 200 are processed in the process chamber 201.

Nozzles 249a to 249c as first to third suppliers are installed in the process chamber 201 so as to penetrate the side wall of the manifold 209. The nozzles 249a to 249c are also referred to as first to third nozzles, respectively. The nozzles 249a to 249c are made of, for example, a heat-resistant material such as quartz or SiC. Gas supply pipes 232a to 232c are connected to the nozzles 249a to 249c, respectively. The nozzles 249a to 249c are different nozzles, and the nozzles 249b and 249c are provided adjacent to the nozzle 249a.

At the gas supply pipes 232a to 232c, mass flow controllers (MFCs) 241a to 241c, which are flow rate controllers (flow control parts), and valves 243a to 243c, which are on-off valves, are installed, respectively, sequentially from the upstream side of a gas flow. Gas supply pipes 232d and 232f are connected to the gas supply pipe 232a on the downstream side of the valve 243a. Gas supply pipes 232e and 232g are connected to the gas supply pipe 232b on the downstream side of the valve 243b. A gas supply pipe 232h is connected to the gas supply pipe 232c on the downstream side of the valve 243c. At the gas supply pipes 232d to 232h, MFCs 241d to 241h and valves 243d to 243h are installed, respectively, sequentially from the upstream side of a gas flow. The gas supply pipes 232a to 232h are made of a metal material such as, for example, stainless steel or the like.

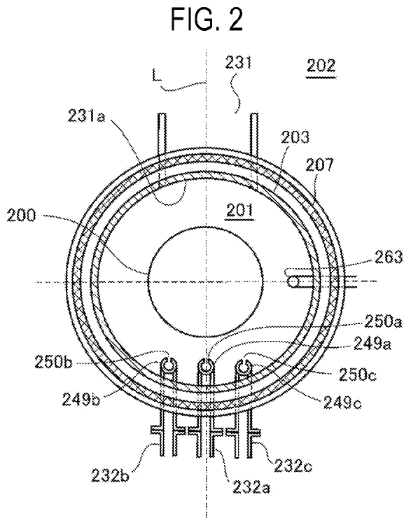

As shown in FIG. 2, the nozzles 249a to 249c are arranged in a space having an annular shape in a plane view between the inner wall of the reaction tube 203 and the wafers 200 so as to extend upward in the arrangement direction of the wafers 200 from the lower portion to the upper portion of the inner wall of the reaction tube 203. In other words, the nozzles 249a to 249c are respectively installed in a region horizontally surrounding a wafer arrangement region, in which the wafers 200 are arranged, on the lateral side of the wafer arrangement region so as to extend along the wafer arrangement region. In a plane view, the nozzle 249a is arranged so as to face the below-described exhaust port 231a on a straight line across the centers of the wafers 200 loaded into the process chamber 201. The nozzles 249b and 249c are arranged so as to sandwich a straight line L passing through the nozzle 249a and the center of the exhaust port 231a from both sides along the inner wall of the reaction tube 203 (the outer peripheral portions of the wafers 200). The straight line L is also a straight line passing through the nozzle 249a and the center of the wafers 200. That is, it can be said that the nozzle 249c is installed on the side opposite to the nozzle 249b with the straight line L interposed therebetween. The nozzles 249b and 249c are arranged line-symmetrically with the straight line L as an axis of symmetry. Gas supply holes 250a to 250c for supplying gases are formed on the side surfaces of the nozzles 249a to 249c, respectively. The gas supply holes 250a to 250c are respectively opened so as to face the exhaust port 231a in a plane view and can supply gases toward the wafers 200. The gas supply holes 250a to 250c are formed from the lower portion to the upper portion of the reaction tube 203.

From the gas supply pipe 232a, a first precursor gas (first precursor) containing a predetermined element is supplied into the process chamber 201 via the MFC 241a, the valve 243a and the nozzle 249a. As the first precursor gas, a gas having no bond between the atoms of the above-mentioned predetermined element in one molecule may be used. Further, as the first precursor gas, a gas having only one atom of the above-mentioned predetermined element in one molecule may be used. As the first precursor gas, it may be possible to use a gas whose dissociation energy, i.e., the energy required for one molecule to decompose into a plurality of molecules is larger than the dissociation energy of a second precursor gas described later. For example, focusing on dissociation caused by thermal energy, as the first precursor gas, it may be possible to use a gas having a thermal decomposition temperature higher than that of the second precursor gas. In this specification, the temperature at which the first precursor gas dissociates (thermally decomposes) when the first precursor gas is present alone in the process chamber 201 is sometimes referred to as a first temperature.

From the gas supply pipe 232b, a hydrogen nitride-based gas, which is a gas containing nitrogen (N) and hydrogen (H), is supplied as a nitriding gas (nitriding agent) into the process chamber 201 via the MFC 241b, the valve 243b and the nozzle 249b.

From the gas supply pipe 232c, an oxygen (O)-containing gas as an oxidizing gas (oxidizing agent) is supplied into the process chamber 201 via the MFC 241c, the valve 243c and the nozzle 249c.

From the gas supply pipe 232d, a second precursor gas (second precursor) containing the above-mentioned predetermined element and having a thermal decomposition temperature lower than that of the first precursor gas is supplied into the process chamber 201 through the MFC 241d, the valve 243d, the gas supply pipe 232a and the nozzle 249a. As the second precursor gas, a gas having a bond between atoms of the predetermined element in one molecule may be used. Further, as the second precursor gas, a gas having two or more atoms of the predetermined element in one molecule may be used. Further, as the second precursor gas, a gas whose dissociation energy is smaller than the dissociation energy of the first precursor gas may be used. For example, focusing on dissociation caused by thermal energy, a gas having a thermal decomposition temperature lower than that of the first precursor gas may be used as the second precursor gas. In this specification, the temperature at which the second precursor gas dissociates (thermally decomposes) when the second precursor gas is present alone in the process chamber 201 is sometimes be referred to as second temperature.

From the gas supply pipe 232e, a hydrogen (H)-containing gas as a reducing gas (reducing agent) is supplied into the process chamber 201 via the MFC 241e, the valve 243e, the gas supply pipe 232b and the nozzle 249b. The H-containing gas does not have an oxidizing action by itself. In the substrate processing process described later, the H-containing gas reacts with an O-containing gas under specific conditions to generate an oxidizing species such as atomic oxygen (O) or the like and acts to improve the efficiency of the oxidizing process. Therefore, it may be considered that the H-containing gas is included in the oxidizing gas.

From the gas supply pipes 232f, 232g and 232h, an inert gas is supplied into the process chamber 201 via the MFCs 241f, 241g and 241h, the valves 243f, 243g and 243h, the gas supply pipes 232a, 232b and 232c, and the nozzles 249a, 249b and 249c, respectively. The inert gas acts as a purge gas, a carrier gas, a diluting gas, and the like.

A first precursor gas supply system is mainly composed of the gas supply pipe 232a, the MFC 241a, and the valve 243a. A nitriding gas supply system is mainly composed of the gas supply pipe 232b, the MFC 241b, and the valve 243b. An oxidizing gas supply system is mainly composed of the gas supply pipe 232c, the MFC 241c, and the valve 243c. The gas supply pipe 232e, the MFC 241e, and the valve 243e may be included in the oxidizing gas supply system. A second precursor gas supply system is mainly composed of the gas supply pipe 232d, the MFC 241d, and the valve 243d. An inert gas supply system is mainly composed of the gas supply pipes 232f to 232h, the MFCs 241f to 241h, and the valves 243f to 243h.

At least one selected from the group of the first precursor gas, the second precursor gas, the nitriding gas, and the oxidizing gas may also be referred to as a film-forming gas. At least one selected from the group of the first precursor gas supply system, the second precursor gas supply system, the nitriding gas supply system, and the oxidizing gas supply system may also be referred to as a film-forming gas supply system.

Among the various gas supply systems described above, any or all of the gas supply systems may be configured as an integrated gas supply system 248 in which the valves 243a to 243h, the MFCs 241a to 241h, and the like are integrated. The integrated gas supply system 248 is connected to each of the gas supply pipes 232a to 232h and is configured so that the operation of supplying various gases into the gas supply pipes 232a to 232h, that is, the opening/closing operation of the valves 243a to 243h, the flow rate adjusting operation by the MFCs 241a to 241h, and the like are controlled by a controller 121 described later. The integrated gas supply system 248 is configured as integral type or division type integrated units and may be attached to and detached from the gas supply pipes 232a to 232h on an integrated unit basis. The maintenance, replacement, expansion, and the like of the integrated gas supply system 248 may be performed on an integrated unit basis.

An exhaust port 231a for exhausting the atmosphere in the process chamber 201 is installed in the lower portion of the side wall of the reaction tube 203. As shown in FIG. 2, the exhaust port 231a is installed at a position facing the nozzles 249a to 249c (gas supply holes 250a to 250c) with the wafers 200 interposed therebetween in a plane view. The exhaust port 231a may be installed to extend from the lower portion to the upper portion of the side wall of the reaction tube 203, that is, along the wafer arrangement region. An exhaust pipe 231 is connected to the exhaust port 231a. The exhaust pipe 231 is made of a metallic material such as stainless steel or the like. A vacuum pump 246 as an evacuation device is connected to the exhaust pipe 231 via a pressure sensor 245 as a pressure detector (pressure detection part) for detecting the pressure inside the process chamber 201 and an APC (Auto Pressure Controller) valve 244 as a pressure regulator (pressure regulation part). The APC valve 244 is configured so that it can perform or stop vacuum evacuation of the interior of the process chamber 201 by being opened and closed in a state in which the vacuum pump 246 is operated. Furthermore, the APC valve 244 is configured so that it can regulate the pressure inside the process chamber 201 by adjusting the valve opening degree based on the pressure information detected by the pressure sensor 245 in a state in which the vacuum pump 246 is operated. An exhaust system is mainly constituted by the exhaust pipe 231, the APC valve 244 and the pressure sensor 245. The vacuum pump 246 may be included in the exhaust system.

A seal cap 219 as a furnace opening lid capable of airtightly closing the lower end opening of the manifold 209 is installed below the manifold 209. The seal cap 219 is made of a metallic material such as, for example, stainless steel or the like, and is formed in a disc shape. On the upper surface of the seal cap 219, there is installed an O-ring 220b as a seal member which abuts against the lower end of the manifold 209. Below the seal cap 219, there is installed a rotator 267 for rotating a boat 217 to be described later. A rotating shaft 255 of the rotator 267 is made of, for example, a metallic material such as stainless steel or the like and is connected to the boat 217 through the seal cap 219. The rotator 267 is configured to rotate the wafers 200 by rotating the boat 217. The seal cap 219 is configured to be raised and lowered in the vertical direction by a boat elevator 115 as an elevating mechanism installed outside the reaction tube 203. The boat elevator 115 is configured as a transfer device (transfer mechanism) that loads and unloads (transfers) the wafers 200 into and out of the process chamber 201 by raising and lowering the seal cap 219.

Below the manifold 209, a shutter 219s is installed as a furnace opening lid capable of airtightly closing the lower end opening of the manifold 209 in a state in which the seal cap 219 is lowered and the boat 217 is unloaded from the process chamber 201. The shutter 219s is made of a metallic material such as stainless steel or the like and is formed in a disk shape. An O-ring 220c as a seal member that comes into contact with the lower end of the manifold 209 is installed on the upper surface of the shutter 219s. The opening/closing operations (the elevating operation, the rotating operation, and the like) of the shutter 219s are controlled by a shutter opener/closer 115s.

A boat 217 as a substrate support tool is configured so as to support a plurality of wafers 200, for example, 25 to 200 wafers 200 in a horizontal posture and in multiple stages while vertically arranging the wafers 200 with the centers thereof aligned with each other, that is, so as to arrange the wafers 200 at intervals. The boat 217 is made of a heat-resistant material such as, for example, quartz or SiC. Heat insulating plates 218 made of a heat-resistant material such as, for example, quartz or SiC, are supported in multiple stages at the bottom of the boat 217.

Inside the reaction tube 203, there is installed a temperature sensor 263 as a temperature detector. By adjusting the state of supply of electric power to the heater 207 based on the temperature information detected by the temperature sensor 263, the temperature inside the process chamber 201 becomes a desired temperature distribution. The temperature sensor 263 is installed along the inner wall of the reaction tube 203.

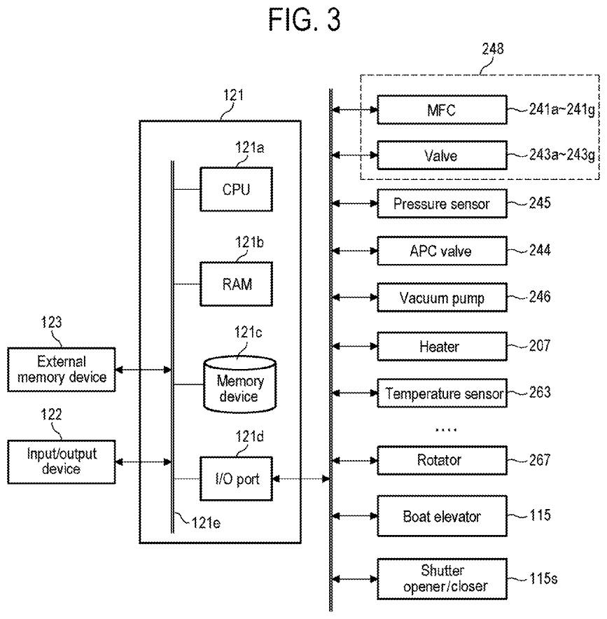

As shown in FIG. 3, the controller 121 as a control part (control unit or control means) is configured as a computer including a CPU (Central Processing Unit) 121a, a RAM (Random Access Memory) 121b, a memory device 121c and an I/O port 121d. The RAM 121b, the memory device 121c and the I/O port 121d are configured to exchange data with the CPU 121a via an internal bus 121e. An input/output device 122 configured as, for example, a touch panel or the like is connected to the controller 121.

The memory device 121c is composed of, for example, a flash memory, an HDD (Hard Disk Drive), an SSD (Solid State Drive), or the like. In the memory device 121c, there are readably stored a control program for controlling the operation of the substrate processing apparatus, a process recipe in which procedures and conditions of substrate processing to be described later are written, and the like. The process recipe is a combination that causes the controller 121 to execute the respective procedures in a below-described substrate processing process so as to obtain a predetermined result. The process recipe functions as a program. Hereinafter, the process recipe, the control program and the like are collectively and simply referred to as a program. Furthermore, the process recipe is also simply referred to as a recipe. When the term “program” is used herein, it may mean a case of including only the recipe, a case of including only the control program, or a case of including both the recipe and the control program. The RAM 121b is configured as a memory area (work area) in which programs, data and the like read by the CPU 121a are temporarily held.

The I/O port 121d is connected to the MFCs 241a to 241h, the valves 243a to 243h, the pressure sensor 245, the APC valve 244, the vacuum pump 246, the temperature sensor 263, the heater 207, the rotator 267, the boat elevator 115, the shutter opener/closer 115s, and the like.

The CPU 121a is configured to read and execute the control program from the memory device 121c and to read the recipe from the memory device 121c in response to an input of an operation command from the input/output device 122 or the like. The CPU 121a is configured to, according to the contents of the recipe thus read, control the flow rate adjustment operation of various gases by the MFCs 241a to 241h, the opening/closing operations of the valves 243a to 243h, the opening/closing operation of the APC valve 244, the pressure regulation operation by the APC valve 244 based on the pressure sensor 245, the start and stop of the vacuum pump 246, the temperature adjustment operation of the heater 207 based on the temperature sensor 263, the rotation and the rotation speed adjustment operation of the boat 217 by the rotator 267, the raising and lowering operation of the boat 217 by the boat elevator 115, the opening/closing operation of the shutter 219s by the shutter opener/closer 115s, and the like.

The controller 121 may be configured by installing, in the computer, the above-described program stored in an external memory device 123. The external memory device 123 includes, for example, a magnetic disk such as an HDD or the like, an optical disk such as a CD or the like, a magneto-optical disk such as an MO or the like, a semiconductor memory such as a USB memory, an SSD or the like, and so forth. The memory device 121c and the external memory device 123 are configured as a computer readable recording medium. Hereinafter, the memory device 121c and the external memory device 123 are collectively and simply referred to as a recording medium. As used herein, the term “recording medium” may include only the memory device 121c, only the external memory device 123, or both. The provision of the program to the computer may be performed by using a communication means or a communication unit such as the Internet or a dedicated line without having to use the external memory device 123.

### (2) Substrate Processing Process

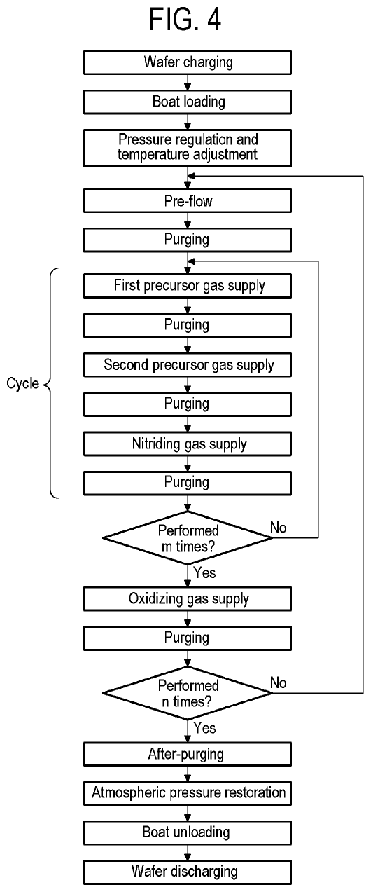

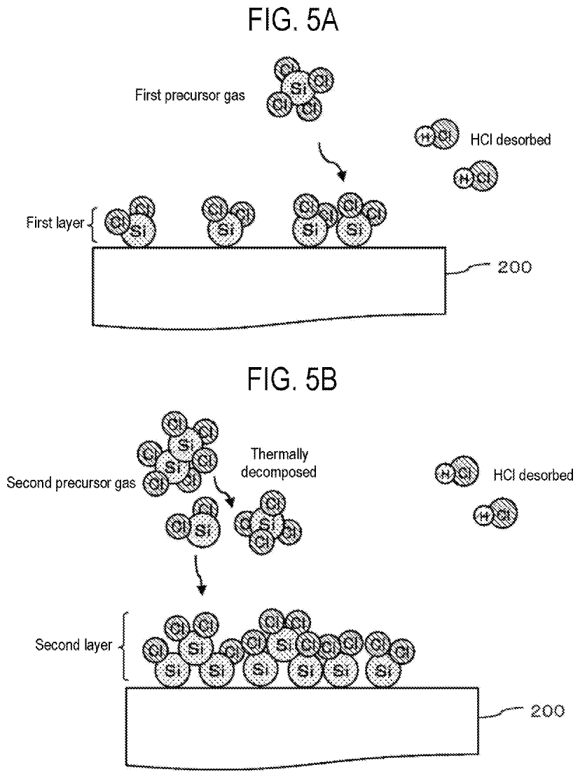

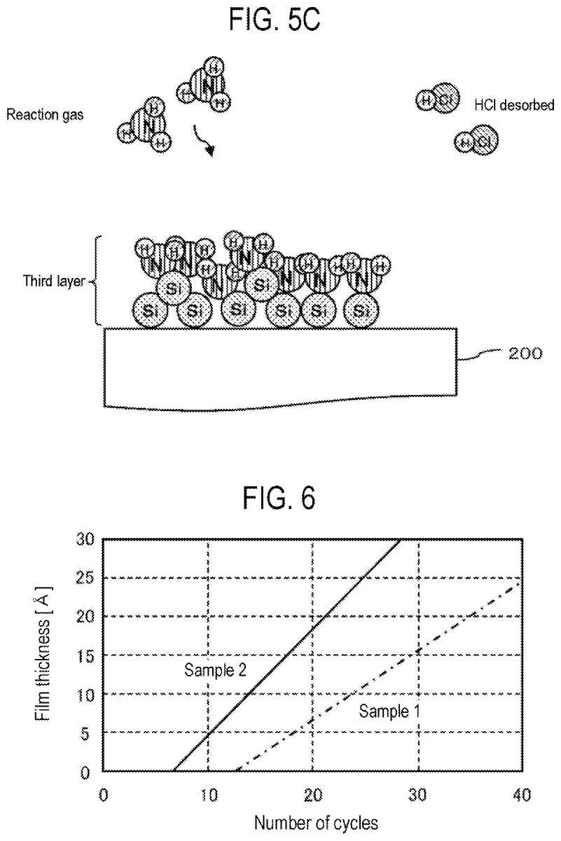

As a process of manufacturing a semiconductor device using the substrate processing apparatus described above, an example of a sequence in which a wafer 200 as a substrate is processed, that is, an example of a film-forming sequence in which a film is formed on a wafer 200 will be described mainly with reference to FIGS. 4 and 5A to 5C. In the following description, the operation of each part constituting the substrate processing apparatus is controlled by the controller 121.

The film-forming sequence according to the present embodiment includes:

a step (nitride film formation) of forming a nitride film containing a predetermined element on a wafer 200 by performing a cycle a predetermined number of times (m times where m is an integer of 1 or more), the cycle including sequentially and non-simultaneously performing:
step a1 of supplying a first precursor gas containing the predetermined element to the wafer 200;
step a2 of supplying a second precursor gas containing the predetermined element and having a thermal decomposition temperature lower than a thermal decomposition temperature of the first precursor gas to the wafer 200; and
step a3 of supplying a nitriding gas to the wafer 200; and

a step (oxidation) of oxidizing the nitride film formed in the nitride film formation and modifying the nitride film into an oxide film containing the predetermined element by supplying an oxidizing gas to the wafer 200.

In the film-forming sequence according to the present embodiment, an oxide film having a predetermined thickness is formed on the wafer 200 by performing a cycle a predetermined number of times (n times where n is an integer of 1 or more), the cycle including non-simultaneously performing the nitride film formation and the oxidation.

Further, in the film-forming sequence according to the present embodiment, a step (pre-flow) of supplying a hydrogen nitride-based gas to the wafer 200 is further performed before the nitride film formation. Specifically, the cycle including non-simultaneously performing the nitride film formation and the oxidation is performed a predetermined number of times (n times where n is an integer of 1 or more), and the pre-flow is performed whenever the cycle is performed.

Hereinafter, a case where the predetermined element includes silicon (Si) will be described. In this case, a silane-based gas described later may be used as the first precursor gas and the second precursor gas. Further, as the nitriding gas, a hydrogen nitride-based gas, which is a gas containing nitrogen (N) and hydrogen (H), may be used. Further, as the oxidizing gas, an oxygen (O)-containing gas and a hydrogen (H)-containing gas may be used. In this case, in the nitride film formation, a silicon nitride film (SiN film) as a nitride film is formed on the wafer 200. In the oxidation, the SiN film formed on the wafer 200 is modified into a silicon oxide film (SiO film) as an oxide film.

In this specification, the above-described film formation sequence may be denoted as follows for the sake of convenience. The same notation is used in the following description of modifications and other embodiments.

[hydrogen nitride-based gas→(first precursor gas→second precursor gas→nitriding gas)×m→oxidizing gas]×n

When the term “wafer” is used herein, it may refer to “a wafer itself” or “a stacked body of a wafer and a predetermined layer or film formed on the surface of the wafer.” When the phrase “a surface of a wafer” is used herein, it may refer to “a surface of a wafer itself” or “a surface of a predetermined layer or the like formed on a wafer.” When the expression “a predetermined layer is formed on a wafer” is used herein, it may mean that “a predetermined layer is directly formed on a surface of a wafer itself” or that “a predetermined layer is formed on a layer or the like formed on a wafer.” When the term “substrate” is used herein, it may be synonymous with the term “wafer.”

### Wafer Charging and Boat Loading

After a plurality of wafers 200 is charged into the boat 217 (wafer charging), the shutter 219s is moved by the shutter opener/closer 115s to open the lower end opening of the manifold 209 (shutter opening). Thereafter, as shown in FIG. 1, the boat 217 supporting the plurality of wafers 200 is lifted by the boat elevator 115 and loaded into the process chamber 201 (boat loading). In this state, the seal cap 219 seals the lower end of the manifold 209 via the O-ring 220b.

### Pressure Regulation and Temperature Adjustment

After the boat loading is completed, the inside of the process chamber 201, that is, the space where the wafer 200 exists, is vacuum-exhausted (decompression-exhausted) by the vacuum pump 246 so as to reach a desired pressure (degree of vacuum). At this time, the pressure inside the process chamber 201 is measured by the pressure sensor 245, and the APC valve 244 is feedback-controlled based on the measured pressure information (pressure regulation). Furthermore, the wafer 200 in the process chamber 201 is heated by the heater 207 to reach a desired processing temperature. At this time, the degree of supplying electric power to the heater 207 is feedback-controlled based on the temperature information detected by the temperature sensor 263 such that the inside of the process chamber 201 has a desired temperature distribution (temperature adjustment). Moreover, the rotation of the wafer 200 by the rotator 267 is started. The exhaust of the process chamber 201 and the heating and rotation of the wafer 200 are continuously performed at least until the processing on the wafer 200 is completed.

### Film-Film Process

Thereafter, the next pre-flow, nitride film formation, and oxidation are performed in the named order.

### Pre-Flow

In this step, a hydrogen nitride-based gas is supplied to the wafer 200 in the process chamber 201.

Specifically, the valve 243b is opened to allow a hydrogen nitride-based gas to flow into the gas supply pipe 232b. The flow rate of the hydrogen nitride-based gas is adjusted by the MFC 241b. The hydrogen nitride-based gas is supplied into the process chamber 201 via the nozzle 249b and is exhausted from the exhaust pipe 231. At this time, the hydrogen nitride-based gas is supplied to the wafer 200 (hydrogen nitride-based gas supply). At this time, the valves 243f to 243h are opened to supply an inert gas into the process chamber 201 via each of the nozzles 249a to 249c. In some of the methods described below, the supply of the inert gas into the process chamber 201 may not be carried out.

An example of a processing condition in this step is described as follows.

Hydrogen nitride-based gas supply flow rate: 100 to 10,000 sccm

Inert gas supply flow rate (each gas supply pipe): 0 to 20,000 sccm

Each gas supply time: 1 to 30 minutes

Processing temperature: 300 to 1,000 degrees C., specifically 700 to 900 degrees C., more specifically 750 to 800 degrees C.

Processing pressure: 1 to 4,000 Pa, specifically 20 to 1,333 Pa

The notation of a numerical range such as “1 to 4,000 Pa” in this specification means that the lower limit value and the upper limit value are included in the range. Therefore, for example, “1 to 4,000 Pa” means “1 Pa or more and 4,000 Pa or less”. The same applies to other numerical ranges. Further, the processing temperature in this specification means the temperature of the wafer 200, and the processing pressure means the pressure in the process chamber 201 which is a space where the wafer 200 exists. In addition, the gas supply flow rate of 0 sccm means a case where the gas is not supplied. These are the same in the following description.

A native oxide film or the like may be formed on the surface of the wafer 200 which is not yet subjected to the film-forming process. By supplying the hydrogen nitride-based gas to the wafer 200 under the above-mentioned condition, it is possible to form NH terminals on the surface of the wafer 200 on which a native oxide film or the like is formed. This makes it possible to efficiently generate a desired film-forming reaction on the wafer 200 in the nitride film formation described later. The NH terminals formed on the surface of the wafer 200 may be regarded as being synonymous with H terminals. Further, since the NH terminals on the surface of the wafer 200 may be reduced by performing the below-described step of oxidizing the nitride film and modifying the nitride film into an oxide film, it is desirable that the pre-flow is performed whenever the cycle including non-simultaneously performing the nitride film formation and the oxidation is performed. However, in consideration of decrease in throughput due to the pre-flow performed in each cycle, the pre-flow may not be performed after the cycle including non-simultaneously performing the nitride film formation and the oxidation is performed once. In addition, the pre-flow may be performed whenever the cycle including non-simultaneously performing the nitride film formation and the oxidation is performed a predetermined number of times (p times where p is an integer of 2 or more and p<n).

After the NH terminals are formed on the surface of the wafer 200 by performing the pre-flow, the valve 243b is closed to stop the supply of the hydrogen nitride-based gas into the process chamber 201. Then, the inside of the process chamber 201 is vacuum-exhausted, and the gas or the like remaining in the process chamber 201 is removed from the inside of the process chamber 201 (purging). At this time, the valves 243f to 243h are opened to supply an inert gas into the process chamber 201.

As the hydrogen nitride-based gas, for example, an ammonia (NH₃) gas, a diazene (N₂H₂) gas, a hydrazine (N₂H₄) gas, a N₃H₈ gas and the like may be used. As the hydrogen nitride-based gas, one or more of these gases may be used.

As the inert gas, for example, a rare gas such as a nitrogen (N₂) gas, an argon (Ar) gas, a helium (He) gas, a neon (Ne) gas, a xenon (Xe) gas or the like may be used. As the inert gas, one or more of these gases may be used. This point is the same in each step described later.

### Nitride Film Formation

After the pre-flow is completed, a nitride film is formed. In this step, the following steps a1 to a3 are performed in the named order.

### Step a1

In this step, a first precursor gas is supplied to the wafer 200 in the process chamber 201.

Specifically, the valve 243a is opened to allow the first precursor gas to flow into the gas supply pipe 232a. The flow rate of the first precursor gas is adjusted by the MFC 241a. The first precursor gas is supplied into the process chamber 201 via the nozzle 249a and is exhausted from the exhaust pipe 231. At this time, the first precursor gas is supplied to the wafer 200 (first precursor gas supply). At this time, the valves 243f to 243h are opened to supply the inert gas into the process chamber 201 via each of the nozzles 249a to 249c. In some of the methods described below, the supply of the inert gas into the process chamber 201 may not be carried out.

An example of a processing condition in this step is described as follows.

First precursor gas supply flow rate: 1 to 2,000 sccm, preferably 100 to 1,000 sccm

Inert gas supply flow rate (each gas supply pipe): 100 to 20,000 sccm

Each gas supply time: 10 to 300 seconds, preferably 30 to 120 seconds

Processing temperature: 400 to 900 degrees C., specifically 500 to 800 degrees C., more preferably 600 to 750 degrees C. (a temperature lower than the first temperature, specifically a temperature lower than the first temperature and higher than the second temperature).

Processing pressure: 1 to 2,666 Pa, preferably 10 to 1,333 Pa

Other processing condition may be the same as the processing condition in the pre-flow described above.

By performing this step under the above-mentioned condition using, for example, a tetrachlorosilane (SiCl₄) gas as the first precursor gas, it is possible to break a part of Si—Cl bonds in SiCl₄ and adsorb Si having dangling bonds on the adsorption sites of the surface of the wafer 200. Further, under the above-mentioned condition, the unbroken Si—Cl bonds in SiCl₄ can be retained as it is. For example, in a state in which Cl is bonded to each of three bonds among the four bonds of Si constituting SiCl₄, Si having dangling bonds is adsorbed on the adsorption sites of the surface of the wafer 200. Further, since Cl held without being broken from the Si adsorbed on the surface of the wafer 200 inhibits the bonding of other Si having dangling bonds to this Si, it is possible to avoid multiple-deposition of Si on the wafer 200. Cl separated from Si forms a gaseous substance such as HCl or Cl₂ and is exhausted from the exhaust pipe 231. When the adsorption reaction of Si proceeds and no adsorption site remains on the surface of the wafer 200, the adsorption reaction is saturated. However, in this step, it is desirable that the supply of the first precursor gas is stopped before the adsorption reaction is saturated and further that this step is finished in a state in which the adsorption sites remain.

As a result, on the wafer 200, a layer containing Si and Cl, that is, a Si-containing layer containing Cl, which has a substantially uniform thickness of less than one atomic layer, is formed as a first layer. FIG. 5A is a schematic diagram showing the state of the surface of the wafer 200 on which the first layer is formed. In this regard, the layer having a thickness of less than one atomic layer means an atomic layer formed discontinuously, and the layer having a thickness of one atomic layer means an atomic layer formed continuously. Further, the expression that the layer having a thickness of less than one atomic layer is substantially uniform means that atoms are adsorbed on the surface of the wafer 200 at a substantially uniform density. Since the first layer is formed on the wafer 200 to have a substantially uniform thickness, the first layer is excellent in step coverage and in-plane thickness.

When a SiCl₄ gas is used as the first precursor gas, if the processing temperature is less than 400 degrees C., it may be difficult for Si to be adsorbed on the wafer 200, which may make it difficult to form the first layer. By setting the processing temperature to 400 degrees C. or higher, it is possible to form the first layer on the wafer 200. By setting the processing temperature to 500 degrees C. or higher, it is possible to reliably obtain the above-mentioned effects. By setting the processing temperature to 600 degrees C. or higher, it is possible to obtain the above-mentioned effects more reliably.

When a SiCl₄ gas is used as the first precursor gas, if the processing temperature exceeds 900 degrees C., it becomes difficult to maintain the unbroken Si—Cl bonds in the molecular structure as it is, and the thermal decomposition rate of the first precursor gas increases. As a result, Si may be multiple-deposited on the wafer 200, which may make it difficult to form a Si-containing layer having a substantially uniform thickness of less than one atomic layer as the first layer. In this case, the above-mentioned first temperature related to the first precursor gas may be considered as a predetermined temperature within a range exceeding 900 degrees C. By setting the processing temperature to 900 degrees C. or lower, it becomes possible to form a Si-containing layer having a substantially uniform thickness of less than one atomic layer as the first layer. By setting the processing temperature to 750 degrees C. or lower, it is possible to reliably obtain the above-mentioned effects.

After forming the first layer on the wafer 200, the valve 243a is closed to stop the supply of the first precursor gas into the process chamber 201. Then, the gas or the like remaining in the process chamber 201 is removed from the inside of the process chamber 201 (purging) by the same processing procedure as the purging in the pre-flow described above.

As the first precursor gas, it may be possible to use a halosilane-based gas which contains only one silicon (Si) as a predetermined element, has no Si—Si bond, and has a molecular structure containing a halogen element bonded to Si. The halogen element includes chlorine (Cl), fluorine (F), bromine (Br), iodine (I), and the like. As the first precursor gas, for example, a chlorosilane-based gas containing Si and Cl may be used.

As the first precursor gas, in addition to the SiCl₄ gas, it may be possible to use, for example, a chlorosilane-based gas such as a monochlorosilane (SiH₃Cl) gas, a dichlorosilane (SiH₂Cl₂) gas, a trichlorosilane (SiHCl₃) gas, or the like. As the first precursor gas, one or more of these gases may be used. As the first precursor gas, in addition to the chlorosilane-based gas, it may also be possible to use, for example, a fluorosilane-based gas such as a tetrafluorosilane (SiF₄) gas, a difluorosilane (SiH₂F₂) gas or the like, a bromosilane-based gas such as a tetrabromosilane (SiBr₄) gas, a dibromosilane (SiH₂Br₂) gas or the like, or an iodosilane-based gas such as a tetraiodosilane (SiI₄) gas, a diiodosilane (SiH₂I₂) gas or the like.

### Step a2

In this step, a second precursor gas is supplied to the wafer 200 in the process chamber 201, that is, the first layer formed on the wafer 200.

Specifically, the valve 243d is opened to allow the second precursor gas to flow into the gas supply pipe 232d. The flow rate of the second precursor gas is controlled by the MFC 241d. The second precursor gas is supplied into the process chamber 201 via the gas supply pipe 232a and the nozzle 249a and is exhausted from the exhaust pipe 231. At this time, the second precursor gas is supplied to the wafer 200 (second precursor gas supply). At this time, the valves 243f to 243h are opened to supply an inert gas into the process chamber 201 via each of the nozzles 249a to 249c. In some of the methods described below, the supply of the inert gas into the process chamber 201 may not be carried out.

An example of a processing condition in this step is described as follows.

Second precursor gas supply flow rate: 1 to 2,000 sccm, specifically 100 to 1,000 sccm

Inert gas supply flow rate (each gas supply pipe): 0 to 20,000 sccm

Each gas supply time: 0.5 to 60 seconds, specifically 1 to 30 seconds

Processing temperature: 500 to 1,000 degrees C., preferably 600 to 800 degrees C., more specifically 650 to 750 degrees C. (a temperature higher than the second temperature, specifically a temperature higher than the second temperature and lower than the first temperature).

Other processing condition may be the same as the processing condition in the pre-flow described above.

By performing this step under the above-mentioned condition using, for example, a hexachlorodisilane (Si₂Cl₆) gas as the second precursor gas, it is possible to thermally decompose Si₂Cl₆ and allow Si having dangling bonds via the thermal decomposition to react with the adsorption sites of the surface of the wafer 200 remaining without the first layer formed in step al so as to be adsorbed on the surface of the wafer 200. At this time, the Si—Si bonds contained in the molecular structure is broken by thermal decomposition so that molecules containing Si having dangling bonds are generated. Since the adsorption site does not exist in the portion where the first layer is formed, the adsorption of Si on the first layer is suppressed. As a result, in this step, a Si-containing layer as a second layer is formed over the surface of the wafer 200 at a substantially uniform thickness, based on the first layer formed over the surface of the wafer 200 at a substantially uniform thickness. Further, Si having dangling bonds due to the thermal decomposition of the second precursor gas are bonded to each other to form Si—Si bonds. By allowing these Si—Si bonds to react with the adsorption sites and the like remaining on the surface of the wafer 200, it is possible to allow the Si—Si bonds to be included in the second layer and to form a layer in which Si is multiple-deposited. That is, by this step, an amount (content ratio) of Si—Si bonds contained in the second layer can be made larger than an amount (content ratio) of Si—Si bonds contained in the first layer. Cl separated from Si forms a gaseous substance such as HCl or Cl₂ and is exhausted from the exhaust pipe 231.

In order to make the amount of Si—Si bonds contained in the second layer larger than the amount of Si—Si bonds contained in the first layer by this step, it is desirable that as described above, the temperature at which the second precursor gas is dissociated (thermally decomposed) is lower than the temperature at which the first precursor gas is dissociated (thermally decomposed). In other words, it is desirable that the second precursor gas is a gas that is more likely to form bonds between atoms of the predetermined element under the same condition than the first precursor gas. For example, it is desirable that the molecule of the second precursor gas contains bonds between atoms of the predetermined element. Further, for example, it is desirable that a composition ratio, which is a ratio of the content of the predetermined element such as Si or the like to the content of a halogen element such as Cl or the like in the molecule of the second precursor gas, is made larger than that of the first precursor gas. As described above, in this step, the selection of the processing condition such as the processing temperature and the like and the selection of the first precursor gas and the second precursor gas are performed such that the bonds between the atoms of the predetermined elements reacting with the adsorption sites remaining on the wafer surface are more likely to be formed than in step a1.

As a result, in this step, as the second layer, a Si-containing layer having a substantially uniform thickness exceeding the thickness of the first layer is formed. From the viewpoint of improving the deposition rate and the like, in the present embodiment, a Si-containing layer having a substantially uniform thickness exceeding one atomic layer is formed as the second layer. FIG. 5B is a schematic diagram showing a state of the surface of the wafer 200 on which the second layer is formed. As used herein, the term “second layer” means the Si-containing layer on the wafer 200, which is formed by performing step al and step a2 once.

When a Si₂Cl₆ gas is used as the second precursor gas, if the processing temperature is less than 500 degrees C., the gas may be difficult to be thermally decomposed, which may make it difficult to form the second layer. By setting the processing temperature to 500 degrees C. or higher, it becomes possible to form the second layer on the first layer. By setting the processing temperature to 600 degrees C. or higher, the above-mentioned effects can be reliably obtained. By setting the processing temperature to 650 degrees C. or higher, the above-mentioned effects can be obtained more reliably.

When a Si₂Cl₆ gas is used as the second precursor gas, if the processing temperature exceeds 1000 degrees C., the thermal decomposition of the second precursor gas becomes excessive and the deposition of Si, which is not self-saturated, tends to proceed rapidly. Therefore, it may be difficult to form the second layer substantially uniformly. By setting the processing temperature to 1,000 degrees C. or lower, it is possible to suppress excessive thermal decomposition of the second precursor gas, and by controlling the deposition of Si which is not self-saturated, it becomes possible to form the second layer substantially uniformly. In this case, the above-mentioned second temperature related to the second precursor gas can be considered as a predetermined temperature within a range exceeding 1,000 degrees C. By setting the processing temperature to 800 degrees C. or lower, the above-mentioned effects can be reliably obtained. By setting the processing temperature to 750 degrees C. or lower, the above-mentioned effects can be obtained more reliably.

Further, it is desirable that the temperature conditions in steps a1 and a2 are substantially the same. This makes it unnecessary to change the temperature of the wafer 200, that is, to change the temperature in the process chamber 201 (change the set temperature of the heater 207) between steps a1 and a2. Therefore, the waiting time until the temperature is stabilized is not needed between the steps, which makes it possible to improve the throughput of the substrate processing process. Accordingly, in steps a1 and a2, it is desirable that the temperature of the wafer 200 is set to a predetermined temperature within the range of, for example, 500 to 900 degrees C., specifically 600 to 800 degrees C., and more specifically 650 to 750 degrees C. In the present embodiment, when the temperature conditions in steps a1 and a2 are substantially the same, the temperature conditions, the first precursor gas and the second precursor gas are selected such that the thermal decomposition of the first precursor gas does not substantially occur (i.e., is suppressed) in step a1, and the thermal decomposition of the second precursor gas occurs (i.e., is promoted) in step a2.

After forming the second layer on the wafer 200, the valve 243d is closed to stop the supply of the second precursor gas into the process chamber 201. Then, the gas or the like remaining in the process chamber 201 is removed from the inside of the process chamber 201 by the same processing procedure as the purging in the pre-flow described above (purging).

As the second precursor gas, it may be possible to use a halosilane-based gas which contains two or more silicon (Si) as the predetermined element, has Si—Si bonds, and has a molecular structure containing a halogen element bonded to Si. The halogen element includes Cl, F, Br, I, and the like. As the second precursor gas, it may be possible to use, for example, a chlorosilane-based gas containing Si and Cl. As the second precursor gas, in addition to the Si₂Cl₆ gas, it may be possible to use, for example, a chlorosilane-based gas such as a monochlorodisilane (Si₂H₅Cl) gas, a dichlorodisilane (Si₂H₄Cl₂) gas, a trichlorodisilane (Si₂H₃Cl₃) gas, a tetrachlorodisilane (Si₂H₂Cl₄) gas, a monochlorotrisilane (Si₃H₅Cl) gas, a dichlorotrisilane (Si₃H₄Cl₂) gas, or the like. As the second precursor gas, one or more of these gases may be used.

As the second precursor gas, it may be possible to use an aminosilane-based gas which contains two or more silicon (Si) as the predetermined element, has Si—Si bonds, and has a molecular structure containing amino groups bonded to Si. As the second precursor gas, it may be possible to use, for example, an aminosilane-based gas such as a trisdimethylaminosilane (Si[N(CH₃)₂]₃H) gas, a bisdiethylaminosilane (SiH₂[N(C₂H5)₂]₂) gas, or the like. As the second precursor gas, one or more of these gases may be used. By using a non-halogen gas as the second precursor gas, it is possible to avoid mixing of halogen into the film to be finally formed on the wafer 200.

### Step a3

In this step, a nitriding gas is supplied to the wafer 200 in the process chamber 201, that is, a layer formed by stacking the first layer and the second layer, which are formed on the wafer 200.

Specifically, the valve 243b is opened to allow a nitriding gas to flow into the gas supply pipe 232b. The flow rate of the nitriding gas is controlled by the MFC 241b. The nitriding gas is supplied into the process chamber 201 via the nozzle 249b and is exhausted from the exhaust pipe 231. At this time, the nitriding gas is supplied to the wafer 200 (nitriding gas supply). At this time, the valves 243f to 243h are opened to supply an inert gas into the process chamber 201 via each of the nozzles 249a to 249c. In some of the methods described below, the supply of the inert gas into the process chamber 201 may not be carried out.

An example of a processing condition in this step is described as follows.

Nitriding gas supply flow rate: 100 to 10,000 sccm, specifically 1,000 to 5,000 sccm

Inert gas supply flow rate (each gas supply pipe): 0 to 20,000 sccm

Each gas supply time: 1 to 120 seconds, specifically 10 to 60 seconds

Processing pressure: 1 to 4,000 Pa, specifically 10 to 1,000 Pa

Other processing condition may be the same as the processing condition in the pre-flow described above.

By performing this step under the above-mentioned condition using, for example, a hydrogen nitride-based gas as the nitriding gas, at least a part of the second layer can be nitrided. Cl contained in the second layer forms a gaseous substance such as HCl and Cl₂ and is exhausted from the exhaust pipe 231. As a result, a silicon nitride layer (SiN layer), which is a nitride layer containing Si and N, is formed on the wafer 200 as a third layer. FIG. 5C is a partially enlarged view of the surface of the wafer 200 on which the third layer is formed.

After forming the third layer on the wafer 200, the valve 243b is closed to stop the supply of the nitriding gas into the process chamber 201. Then, the gas or the like remaining in the process chamber 201 is removed from the inside of the process chamber 201 by the same processing procedure as the purging in the pre-flow described above (purging).

As the nitriding gas, it may be possible to use, for example, a hydrogen nitride-based gas such as an ammonia (NH₃) gas, a diazene (N₂H₂) gas, a hydrazine (N₂H₄) gas, an N₃H₈ gas, or the like. As the nitriding gas, one or more of these gases may be used. In addition, as the nitriding gas, the same gas as the hydrogen nitride-based gas used in the pre-flow may be used.

### Performing a Predetermined Number of Times

By performing a cycle a predetermined number of times (m times where m is an integer of 1 or more), the cycle including sequentially performing the above-mentioned steps a1 to a3 non-simultaneously, that is, without synchronization, a nitride film having a predetermined composition ratio and a predetermined film thickness can be formed on the wafer 200. It is desirable that the above cycle is repeated a plurality of times. That is, it is desirable that the thickness of the nitride layer formed per cycle is made smaller than a desired film thickness, and the above cycle is repeated a plurality of times until the desired film thickness is reached. However, it is desirable that the thickness of the nitride film formed on the wafer 200 by performing the cycle a predetermined number of times is made such that the effect of oxidation performed after this step is applied over the entire nitride film.

In the nitride film formation, it is desirable that at least one selected from the group of a ratio of the supply time T₁ of the first precursor gas in step a1 to the supply time T₂ of the second precursor gas in step a2, a ratio of the supply flow rate F₁ of the first precursor gas in step a1 to the supply flow rate F₂ of the second precursor gas in step a2, and a ratio of the processing pressure P₁ in step a1 to the processing pressure P₂ in step a2 may be adjusted such that the ratio of the predetermined element (Si) in the nitride film formed on the wafer 200 is larger than the ratio of the predetermined element in the nitride film (e.g., Si: N=3:4 in the case of a SiN film) when the nitride film has a stoichiometric composition (so that the nitride film becomes a film which is rich in the predetermined element).

For example, by setting the supply time T₂ of the second precursor gas in step a2 to be longer than the supply time T₁ of the first precursor gas in step a1 (so that T₂/T₁>1), it is possible to control the ratio of the predetermined element in the nitride film formed on the wafer 200 in an increasing direction (in a direction of having a predetermined element-rich composition).

Further, for example, by setting the supply flow rate F₂ of the second precursor gas in step a2 to be larger than the supply flow rate F₁ of the first precursor gas in step a1 (so that F₂/F₁>1), it is possible to control the ratio of the predetermined element in the nitride film formed on the wafer 200 in an increasing direction (in a direction of having a predetermine element-rich composition).

In addition, for example, by setting the processing pressure P₂ in step a2 to be higher than the processing pressure P₁ in step a1 (so that P₂/P₁>1), it is possible to control the ratio of the predetermined element in the nitride film formed on the wafer 200 in an increasing direction (in a direction of having a predetermine element-rich composition).

### Oxidation

After the nitride film formation is completed, an oxidizing gas is supplied to the wafer 200 in the process chamber 201, that is, the SiN film formed on the wafer 200.

Specifically, the valves 243c and 243e are opened to allow an O-containing gas and a H-containing gas to flow into the gas supply pipes 232c and 232e, respectively. The flow rates of the O-containing gas and the H-containing gas flowing through the gas supply pipes 232c and 232e are adjusted by the MFCs 241c and 241e, respectively. The O-containing gas and the H-containing gas are supplied into the process chamber 201 via the gas supply pipes 232b and the nozzles 249c and 249b, respectively. The O-containing gas and the H-containing gas are mixed and reacted with each other in the process chamber 201 and are then exhausted from the exhaust port 231a. At this time, an oxygen-containing and water (H₂O)-free oxidizing species such as atomic oxygen or the like generated by the reaction between the O-containing gas and the H-containing gas is supplied to the heated wafer 200 at a reduced pressure atmosphere (O-containing gas+H-containing gas supply). At this time, the valves 243f to 243h are opened to supply an inert gas into the process chamber 201 via each of the nozzles 249a to 249c. In some of the methods described below, the supply of the inert gas into the process chamber 201 may not be carried out.

An example of a processing condition in this step is described as follows.

O-containing gas supply flow rate: 100 to 10,000 sccm, specifically 1,000 to 5,000 sccm

H-containing gas supply flow rate: 100 to 10,000 sccm, specifically 1000 to 5000 sccm

Inert gas supply flow rate (each gas supply pipe): 0 to 20,000 sccm

Each gas supply time: 1 to 120 seconds, specifically 10 to 60 seconds

Processing pressure: 1 to 2000 Pa, specifically 10 to 1,333 Pa

Other processing condition may be the same as the processing condition in the pre-flow described above.

By performing this step under the above-mentioned condition using, for example, O-containing gas+H-containing gas as the oxidizing gas, the SiN film, which is the nitride film formed on the wafer 200, can be oxidized and modified into a film containing Si and O, that is, a silicon oxide film (SiO film) as an oxide film. By appropriately adjusting the thickness of the nitride film formed on the wafer 200 in the above-mentioned nitride film formation, the effect of oxidation in this step can be applied over the entire nitride film. That is, the entire nitride film can be modified into an oxide film.

After modifying the nitride film formed on the wafer 200 into an oxide film, the valves 243c and 243e are closed to stop the supply of the O-containing gas and the H-containing gas into the process chamber 201. Then, the gas or the like remaining in the process chamber 201 is removed from the inside of the process chamber 201 by the same processing procedure as the purging in the pre-flow described above (purging).

As the oxidizing gas, it may be possible to use oxygen (O₂) gas+hydrogen (H₂ gas), an ozone (O₃) gas, a water vapor (H₂O gas), a gas containing O radicals, a gas containing OH radicals, a gas containing plasma-excited O₂, and the like. As the oxidation gas, one or more of these gases may be used.

### Performing a Predetermined Number of Times

By performing a cycle a predetermined number of times (n times where n is an integer of 1 or more), the cycle including sequentially performing the pre-flow, the nitride film formation and the oxidation non-simultaneously, that is, without synchronization, a SiO film having a predetermined composition ratio and a predetermined film thickness can be formed on the wafer 200. It is desirable that the above cycle is repeated a plurality of times. That is, it is desirable that the thickness of the oxide film formed per cycle is made smaller than a desired film thickness, and the above cycle is repeated a plurality of times until the desired film thickness is reached.

### After-Purging and Atmospheric Pressure Restoration

After the formation of the oxide film having a desired film thickness on the wafer 200 is completed, an inert gas as a purge gas is supplied into the process chamber 201 from each of the nozzles 249a to 249c and is exhausted from the exhaust port 231a. As a result, the inside of the process chamber 201 is purged, and the gas, reaction by-products, and the like remaining in the process chamber 201 are removed from the inside of the process chamber 201 (after-purging). Thereafter, the atmosphere in the process chamber 201 is replaced with the inert gas (inert gas replacement), and the pressure in the process chamber 201 is restored to the atmospheric pressure (atmospheric pressure restoration).

### Boat Unloading and Wafer Discharging

Thereafter, the seal cap 219 is lowered by the boat elevator 115 to open the lower end of the manifold 209. Then, the processed wafers 200 supported by the boat 217 are unloaded from the lower end of the manifold 209 to the outside of the reaction tube 203 (boat unloading). After the boat is unloaded, the shutter 219s is moved and the lower end opening of the manifold 209 is sealed by the shutter 219s via the O-ring 220c (shutter closing). The processed wafers 200 are discharged out of the boat 217 after being unloaded from the reaction tube 203 (wafer discharging).

### (3) Effects of the Present Embodiment

According to the present embodiment, one or more of the following effects may be obtained.

(a) In this embodiment, step a1 of supplying the first precursor gas and step a2 of supplying the second precursor gas are performed in one cycle. Therefore, it is possible to achieve both the effect of improving the step coverage and the in-plane film thickness uniformity of the nitride film formed on the wafer 200 and the effect of increasing the deposition rate of the nitride film. Therefore, it is possible to achieve both the effect of improving the step coverage and the in-plane film thickness uniformity of the oxide film to be finally formed on the wafer 200 and the effect of increasing the deposition rate of the oxide film.

This is because when the first precursor gas, which has a thermal decomposition temperature higher than that of the second precursor gas and is less likely to be thermally decomposed than the second precursor gas, is supplied to the wafer 200 under the above-mentioned processing condition, the first layer having a substantially uniform thickness of less than one atomic layer is formed on the wafer 200. If it is assumed that a cycle of sequentially performing step a1 of supplying the first precursor gas and step a3 of supplying the nitriding gas without performing step a2 is performed a predetermined number of times, it is possible to have good step coverage characteristic and in-plane film thickness uniformity of the nitride film to be finally formed on the wafer 200 because the thickness of the nitride layer formed per cycle is uniform over the wafer plane. On the other hand, since the thickness of the nitride layer formed per cycle is thin, it may be difficult to increase the deposition rate of the nitride film formed on the wafer 200. That is, it is difficult to achieve both the effect of improving the step coverage and the in-plane film thickness uniformity of the oxide film to be finally formed on the wafer 200 and the effect of increasing the deposition rate of the oxide film.

Meanwhile, when the second precursor gas, which has a thermal decomposition temperature lower than that of the first precursor gas and is more easily thermally decomposed than the first precursor gas, is supplied to the wafer 200 under the above-mentioned processing condition, a second layer, which contains bonds between predetermined elements and has a thickness exceeding one atomic layer the wafer 200, is formed on the wafer 200. If it is assumed that a cycle of sequentially performing step a2 of supplying the second precursor gas and step a3 of supplying the nitriding gas without performing step a1 is performed a predetermined number of times, it is possible to improve the deposition rate of the nitride film to be finally formed on the wafer 200 because the thickness of the nitride layer formed per cycle is made thick. On the other hand, since the thickness of the nitride layer formed per cycle is likely to be non-uniform in the wafer plane, it may be difficult to improve the step coverage and the in-plane film thickness uniformity of the nitride film formed on the wafer 200. That is, it is difficult to achieve both the effect of improving the step coverage and the in-plane film thickness uniformity of the oxide film to be finally formed on the wafer 200 and the effect of increasing the deposition rate of the oxide film.

In the present embodiment, since both steps a1 and a2 are performed, it is possible to achieve both the effects obtained from the respective steps. For example, by terminating step a1 before the adsorption reaction of the predetermined element on the wafer 200 is saturated and proceeding to step a2 having a relatively high deposition rate, it is possible to improve the deposition rate as compared with the case where only step a1 is executed for the same time. Further, by forming the first layer having relatively excellent thickness uniformity in step a1 and then forming the second layer based on the first layer in step a2, it is possible to improve the step coverage and the in-plane film thickness uniformity of the nitride film formed on the wafer 200 as compared with the case where only step a2 is executed. That is, it is possible to achieve both the effect of improving the step coverage and the in-plane film thickness uniformity of the oxide film to be finally formed on the wafer 200 and the effect of increasing the deposition rate of the oxide film.

(b) In the present embodiment, by performing step a1 before step a2 and then performing step a2 in each cycle, it is possible to increase the deposition rate of the nitride film while fully exhibiting the step coverage and the in-plane film thickness uniformity of the nitride film to be finally formed on the wafer 200. This makes it possible to increase the deposition rate of the oxide film while sufficiently exhibiting the step coverage and the in-plane film thickness uniformity of the oxide film finally to be formed on the wafer 200.

If, in each cycle, step a2 is performed before step a1 and then step a1 is performed, atoms containing bonds between predetermined elements generated by thermal decomposition tend to be adsorbed irregularly on the surface of the wafer 200 in step a2. Therefore, a layer having a non-uniform in-plane thickness may be formed as a base of the layer to be formed in step a1. For that reason, the technical significance of step a1 of forming a layer having a substantially uniform thickness during the film-forming process is likely to be lost.

On the other hand, according to the present embodiment, in each cycle, step a1 is performed before step a2, and then step a2 is performed. Therefore, a film having a substantially uniform thickness can be formed as a base of the layer to be formed in step a2. Accordingly, it is possible to sufficiently demonstrate the technical significance of step a1 of forming a layer having a substantially uniform thickness during the film-forming process.

(c) In the present embodiment, it is possible to widely control a composition ratio of a predetermined element and N in the nitride film formed on the wafer 200. This makes it possible to adjust the composition of the oxide film to be finally formed on the wafer 200 to a desired composition.

This is because, by reducing a ratio B/A of the supply amount B of the second precursor gas to the substrate per cycle to the supply amount A of the first precursor gas to the substrate per cycle, it is possible to reduce a ratio of the bonds between the predetermined elements contained in the second layer and to control the thickness of the second layer in a reducing direction. By reducing the thickness of the second layer, that is, the layer to be nitrided in step a3, it is possible to control the composition ratio of the nitride film formed on the wafer 200 in a direction that the composition ratio of the predetermined element becomes smaller (that is, the predetermined element becomes poor). For example, by reducing the ratio B/A, the thickness of the second layer is made thin within a range of the thickness exceeding one atomic layer. Thus, it is possible to control the composition ratio of the predetermined element so as to be smaller than the composition ratio in the stoichiometric composition of the nitride film. This makes it possible to adjust the composition of the oxide film to be finally formed on the wafer 200 to a desired composition.

Further, by increasing the ratio B/A, it is possible to increase the ratio of the bonds between the predetermined elements contained in the second layer and to control the thickness of the second layer in an increasing direction. By increasing the thickness of the second layer, that is, the layer to be nitrided in step a3, it is possible to control the composition ratio of the nitride film formed on the wafer 200 in a direction that the composition ratio of the predetermined element becomes larger (i.e., the composition of the nitride film becomes a predetermined element-rich composition). For example, by increasing the ratio B/A, the thickness of the second layer is increased within the range of the thickness exceeding one atomic layer. Thus, it is possible to control the composition ratio of the predetermined element so as to be larger than the composition ratio in the stoichiometric composition of the nitride film. This makes it possible to adjust the composition of the oxide film to be finally formed on the wafer 200 to a desired composition.

When the nitride film formed on the wafer 200 is a SiN film or the like, the larger the composition ratio of N in the nitride film (i.e., the smaller the composition ratio of the predetermined element), the smaller the oxidation rate in the subsequent oxidation process. Therefore, by setting the composition of the nitride film formed on the wafer 200 to a predetermined element-rich composition, it is possible to improve the efficiency of the subsequent oxidation process and to increase the deposition rate of the oxide film. As a result, even if the thickness of the nitride film formed in each cycle is increased, the effect of oxidation is likely to be applied over the entire nitride film. Therefore, it is possible to improve the throughput.

The above-mentioned ratio B/A can be controlled by, for example, adjusting a magnitude of a ratio T₂/T₁ of the supply time T₂ of the second precursor gas per cycle to the supply time T₁ of the first precursor gas per cycle, that is, adjusting the supply time of the first precursor gas and the second precursor gas per cycle. In addition, the above-mentioned ratio B/A can also be controlled by adjusting a magnitude of a ratio F₂/F₁ of the supply flow rate F₂ of the second precursor gas to the supply flow rate F₁ of the first precursor gas.

Further, by adjusting a magnitude of the processing pressure P2 in step a2 and controlling a thermal decomposition rate of the second precursor gas, it is possible to control a composition ratio which is a ratio of the content of the predetermined element to the content of N in the nitride film formed on the wafer 200. This makes it possible to adjust the composition of the oxide film to be finally formed on the wafer 200 to a desired composition.

For example, by reducing the processing pressure P₂, it is possible to control the thickness of the second layer in a reducing direction. By reducing the thickness of the second layer, that is, the layer to be nitrided in step a3, the composition ratio of the nitride film formed on the wafer 200 can be controlled such that the composition ratio of the predetermined element becomes smaller. This makes it possible to adjust the composition of the oxide film to be finally formed on the wafer 200 to a desired composition.

Further, by setting the processing pressure P₂ to be larger than the processing pressure P₁ in step a1, it is possible to control the thickness of the second layer in an increasing direction. By increasing the thickness of the second layer, that is, the layer to be nitrided in step a3, it is possible to control the composition ratio of the nitride film formed on the wafer 200 such that the composition ratio of the predetermined element increases (that is, the predetermined element becomes rich). This makes it possible to adjust the composition of the oxide film to be finally formed on the wafer 200 to a desired composition. Further, by setting the composition of the nitride film formed on the wafer 200 to a predetermined element-rich composition, it is possible to improve the efficiency of the subsequent oxidation process and to increase the deposition rate of the oxide film.

(d) In the present embodiment, the processing temperature in step a1 is set to be lower than the thermal decomposition temperature of the first precursor gas (first temperature), and the processing temperature in step a2 is set to be higher than the thermal decomposition temperature of the second precursor gas (second temperature). Therefore, the above-mentioned effect can be reliably obtained.

This is because the processing temperature is set to a temperature lower than the first temperature in step a1, whereby thermal decomposition of the first precursor gas can be suppressed, and the step coverage and the in-plane film thickness uniformity of the nitride film formed on the wafer 200 can be improved. Further, it becomes possible to control the composition ratio of the nitride film so as to be closer to the composition ratio in the stoichiometric composition. This makes it possible to improve the step coverage and the in-plane film thickness uniformity of the oxide film to be finally formed on the wafer 200 and to adjust the composition of the oxide film to a desired composition.

Further, since the processing temperature is set to a temperature higher than the second temperature in step a2, it is possible to maintain appropriate thermal decomposition of the second precursor gas and to improve the deposition rate of the nitride film formed on the wafer 200. Further, the composition ratio of the nitride film can be controlled in a direction such that the composition of the nitride film becomes a predetermined element-rich composition. This makes it possible to adjust the composition of the oxide film to be finally formed on the wafer 200 to a desired composition. Further, by setting the composition of the nitride film formed on the wafer 200 to a predetermined element-rich composition, it is possible to improve the efficiency of the subsequent oxidation process and to increase the deposition rate of the oxide film.

(e) The above-mentioned effects can also be obtained in the case of using the above-mentioned various hydrogen nitride-based gases, the above-mentioned various first precursor gases, the above-mentioned various second precursor gases, the above-mentioned various nitriding gases, the above-mentioned various oxidizing gases, and the above-mentioned various inert gases.

### Other Embodiments of the Present Disclosure

The embodiments of the present disclosure have been specifically described above. However, the present disclosure is not limited to the above-described embodiments, and various changes may be made without departing from the gist thereof.

In the above-described embodiment, there has been described the example in which a series of steps from the nitride film formation to the oxidation is performed in the same process chamber 201 (in-situ). However, the present disclosure is not limited to such an embodiment. For example, the nitride film formation and the oxidation may be performed in separate process chambers (ex-situ). In this case as well, the same effects as those of the above-described embodiment can be obtained. If a series of steps are performed in-situ, the wafer 200 is not exposed to the atmosphere on the way and can be consistently processed while being placed under vacuum, which makes it possible to perform stable substrate processing. Further, if some steps are performed ex-situ, the temperature in each process chamber can be set in advance to, for example, a processing temperature at each step or a temperature close to the processing temperature. This makes it possible to shorten the time required for temperature adjustment and to enhance the production efficiency.

In the above-described embodiment, there has been described the example in which the execution period of step a1 and the execution period of step a2 do not overlap with each other. The present disclosure is not limited thereto. For example, the execution period of step a1 and at least a part of the execution period of step a2 may be overlapped with each other. By doing so, in addition to the above-mentioned effects, it is possible to shorten the cycle time and to improve the throughput of the substrate processing.

It is desirable that the recipe used for each process is prepared individually according to the processing contents and are stored in the memory device 121c via an electric communication line or an external memory device 123. When starting each process, it is desirable that the CPU 121a properly selects an appropriate recipe from a plurality of recipes stored in the memory device 121c according to the contents of the process. This makes it possible to form films of various film types, composition ratios, film qualities and film thicknesses with high reproducibility in one substrate processing apparatus. In addition, the burden on an operator can be reduced, and each process can be quickly started while avoiding operation mistakes.

The above-described recipes are not limited to the newly prepared ones, but may be prepared by, for example, changing the existing recipes already installed in the substrate processing apparatus. In the case of changing the recipes, the recipes after the change may be installed in the substrate processing apparatus via an electric communication line or a recording medium in which the recipes are recorded. In addition, the input/output device 122 provided in the existing substrate processing apparatus may be operated to directly change the existing recipes already installed in the substrate processing apparatus.

In the above-described embodiment, there has been described an example in which a film is formed using a batch type substrate processing apparatus for processing a plurality of substrates at a time. The present disclosure is not limited to the above-described embodiment, but may be suitably applied to, for example, a case where a film is formed using a single-wafer type substrate processing apparatus for processing one or several substrates at a time. Furthermore, in the above-described embodiment, there has been described an example in which a film is formed using a substrate processing apparatus having a hot wall type process furnace. The present disclosure is not limited to the above-described embodiment but may also be suitably applied to a case where a film is formed using a substrate processing apparatus having a cold wall type process furnace.

Even when these substrate processing apparatuses are used, each processing can be performed under the same processing procedure and processing conditions as those of the above-described embodiment and modifications, and the same effects as those of the above-described embodiment and modifications can be obtained.

Further, in the above-described embodiment, there has been described the example in which the SiO film is formed as the oxide film. The present disclosure is not limited to the above-described embodiment and may also be suitably applied to, for example, a case where an oxide film containing at least one element selected from the group of a metal element and a Group 14 element as a predetermined element is formed. In this regard, examples of the metal element include aluminum (Al), titanium (Ti), zirconium (Zr), hafnium (Hf), molybdenum (Mo), lanthanum (La), and the like. The Group 14 element includes, for example, germanium (Ge).

The above-described embodiments and modifications may be used in combination as appropriate. The processing procedure and processing conditions at this time may be, for example, the same as the processing procedures and processing conditions of the above-described embodiment and modifications.

### EXAMPLE

As samples 1 and 2, a nitride film (SiN film) was formed on a wafer using the substrate processing apparatus shown in FIG. 1.

Sample 1 was produced by performing a cycle that includes alternately performing steps a1 and a3 a predetermined number of times without performing step a2. The processing conditions in each step were set to predetermined conditions within the processing condition range described in the above embodiment. Sample 2 was produced by performing a cycle that includes alternately performing steps a2 and a3 a predetermined number of times without performing step a1. The processing conditions in step a2 were set to predetermined conditions within the processing condition range described in the above embodiment. Other processing conditions are the same as those in the production of sample 1.

Then, the film thickness of the nitride film of each sample was measured per each cycle. The results are shown in FIG. 6. The horizontal axis in FIG. 6 indicates the number of cycles performed, and the vertical axis indicates the thickness of the nitride film [Å]. Referring to FIG. 6, it can be noted that the nitride film of sample 2 produced by using the second precursor gas has a shorter incubation time and a higher cycle rate than those of the nitride film of sample 1 produced by using the first precursor gas.

Further, as samples 3 and 4, a SiN film was formed on the wafer using the substrate processing apparatus shown in FIG. 1. As the wafer, a wafer with a trench structure having a groove width of about 50 nm, a groove depth of about 10 μm, and an aspect ratio of about 200 on the surface thereof was used.

Sample 3 was produced by performing a cycle that includes alternately performing steps a2 and a3 a predetermined number of times without performing step a1. Sample 4 was produced by performing a cycle that includes sequentially performing steps a1 to a3 a predetermined number of times. Specifically, in sample 4, the supply time of the first precursor gas in step a1 was set to 60 seconds. In samples 3 and 4, the supply time of the second precursor gas in step a2 was set to 9 seconds. Other processing conditions were common conditions within the processing condition range in the above-described embodiment, including the number of cycles performed and the amount of gas supplied.

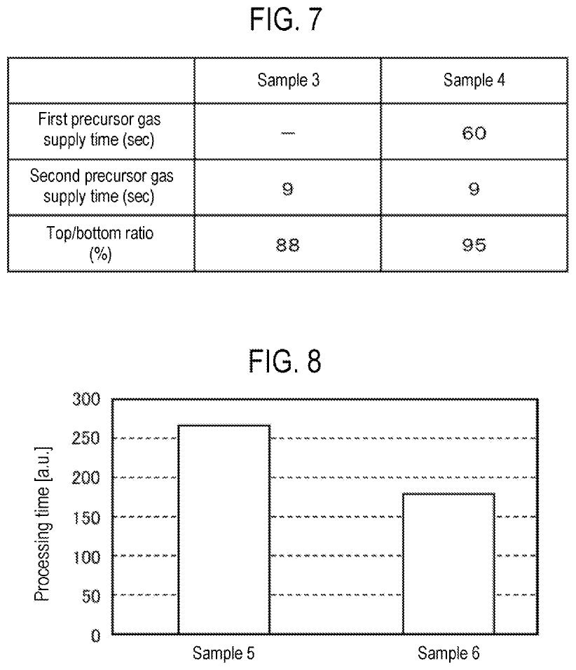

Then, the top/bottom ratio (%) in each of the nitride films of samples 3 and 4 was measured. The results are shown in FIG. 7. The “top/bottom ratio (%)” is a percentage of the thickness of the film formed in the upper portion of the groove of the trench structure to the thickness of the film formed in the lower portion of the groove of the trench structure. The top/bottom ratio (%) is calculated by the formula of C/D×100, where C and D are the thicknesses of the films formed in the upper portion and the lower portion of the groove of the trench structure.

Referring to FIG. 7, it can be seen that the top/bottom ratio in sample 4 is larger (close to 100) than the top/bottom ratio in sample 3. That is, it can be noted that the nitride film of sample 4 produced by supplying both the first precursor gas and the second precursor gas is more excellent in step coverage and in-plane film thickness uniformity than the nitride film of sample 3 produced by supplying only the second precursor gas without supplying the first precursor gas.

Further, as samples 5 and 6, an oxide film (SiO film) was formed on the wafer by oxidizing the nitride film formed on the wafer using the substrate processing apparatus shown in FIG. 1.

Sample 5 was produced by performing a cycle that includes alternately performing steps a1 and a3 a predetermined number of times without performing step a2, when forming a nitride film. Sample 6 was produced by performing a cycle that includes sequentially performing steps a1 to a3 a predetermined number of times, when forming a nitride film. The processing conditions in each step are common conditions within the processing condition range in the above-described embodiment. The number of repetitions (n times) of the cycle including nitride film formation and oxidation was set to 3 in each sample.

Then, in samples 5 and 6, the processing time (a.u.) required for the oxide film to have a predetermined film thickness was measured. The results are shown in FIG. 8. The horizontal axis in FIG. 8 indicates each sample, and the vertical axis indicates the processing time (a.u.) required for the oxide film to have a predetermined film thickness. Referring to FIG. 8, it can be noted that sample 6, in which the nitride film is formed by performing the cycle that includes sequentially performing steps a1 to a3 a predetermined number of times, has a shorter required processing time and a higher deposition rate than sample 5 in which step a2 is not performed when forming the nitride film.

According to the present disclosure in some embodiments, it is possible to provide a technique capable of improving the characteristics of a film formed on a substrate.
While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of manufacturing a semiconductor device, comprising:
(a) forming a nitride film containing a predetermined element on a substrate by performing a cycle a predetermined number of times, the cycle including sequentially performing:
(a-1) supplying a first precursor gas containing the predetermined element to the substrate;
(a-2) supplying a second precursor gas containing the predetermined element and having a thermal decomposition temperature lower than a thermal decomposition temperature of the first precursor gas to the substrate; and
(a-3) supplying a nitriding gas to the substrate; and
(b) oxidizing the nitride film formed in (a) and modifying the nitride film into an oxide film containing the predetermined element by supplying an oxidizing gas to the substrate.

2. The method of claim 1, wherein the oxide film having a predetermined thickness is formed on the substrate by performing, a predetermined number of times, a cycle that includes performing (a) and (b).

3. The method of claim 2, wherein a thickness of the nitride film formed in (a) is made to a thickness at which an effect of oxidation in (b) is applied over an entirety of the nitride film in a thickness direction.

4. The method of claim 1, wherein (a) and (b) are performed in a same process chamber.

5. The method of claim 1, wherein as the first precursor gas, a gas whose dissociation energy required for decomposing one molecule into a plurality of molecules is larger than a dissociation energy of the second precursor gas is used.

6. The method of claim 1, wherein the first precursor gas does not contain a bond between atoms of the predetermined element in one molecule, and
wherein the second precursor gas contains a bond between atoms of the predetermined element in one molecule.

7. The method of claim 6, wherein the first precursor gas contains only one atom of the predetermined element in one molecule, and
wherein the second precursor gas contains two or more atoms of the predetermined element in one molecule.

8. The method of claim 1, wherein the first precursor gas is at least one gas selected from the group consisting of a SiCl₄ gas, a SiH₂Cl₂ gas, a SiH₃Cl gas, and a SiHCl₃ gas, and
wherein the second precursor gas is at least one gas selected from the group consisting of a Si₂Cl₆ gas, a Si₂H₅Cl gas, a Si₂H₄Cl₂ gas, a Si₂H₃Cl₃ gas, a Si₂H₂Cl₄ gas, a Si₃H₅Cl gas, and a Si₃H₄Cl₂ gas.

9. The method of claim 1, wherein in (a-1), a temperature of the substrate is set to a temperature at which the first precursor gas is not thermally decomposed, and
wherein in (a-2), a temperature of the substrate is set to a temperature at which the second precursor gas is thermally decomposed.

10. The method of claim 1, further comprising:
(c) supplying a hydrogen nitride-based gas to the substrate before performing (a).

11. The method of claim 10, wherein a cycle that includes performing (a) and (b) is performed a predetermined number of times, and (c) is performed whenever the cycle is performed.

12. The method of claim 10, wherein the nitriding gas is the hydrogen nitride-based gas.

13. The method of claim 10, wherein the hydrogen nitride-based gas is at least one gas selected from the group consisting of a NH₃ gas, a N₂H₂ gas, a N₂H₄ gas, and a N₃H₈ gas.

14. The method of claim 1, wherein the oxidizing gas is at least one gas selected from the group consisting of an O₂ gas, an O₃ gas, an O₂ gas and a H₂ gas, a H₂O gas, a gas containing O radicals, a gas containing OH radicals, and a gas containing plasma-excited O₂.

15. The method of claim 1, wherein in (b), an O₂ gas and a H₂ gas are supplied to the substrate heated at a reduced pressure atmosphere.

16. The method of claim 1, wherein in (a), at least one selected from the group of a ratio of a supply time of the first precursor gas in (a-1) to a supply time of the second precursor gas in (a-2), a ratio of a supply flow rate of the first precursor gas in (a-1) to a supply flow rate of the second precursor gas in (a-2), and a ratio of a processing pressure in (a-1) to a processing pressure in (a-2) is adjusted such that a ratio of the predetermined element in the nitride film becomes larger than a ratio of the predetermined element in a nitride film that has a stoichiometric composition.

17. The method of claim 16, wherein the supply time of the second precursor gas in (a-2) is set to be longer than the supply time of the first precursor gas in (a-1).

18. The method of claim 16, wherein the supply flow rate of the second precursor gas in (a-2) is set to be larger than the supply flow rate of the first precursor gas in (a-1).

19. The method of claim 16, wherein the processing pressure in (a-2) is set to be higher than the processing pressure in (a-1).

20. A substrate processing method, comprising:
(a) forming a nitride film containing a predetermined element on a substrate by performing a cycle a predetermined number of times, the cycle including sequentially performing:
(a-1) supplying a first precursor gas containing the predetermined element to the substrate;
(a-2) supplying a second precursor gas containing the predetermined element and having a thermal decomposition temperature lower than a thermal decomposition temperature of the first precursor gas to the substrate; and
(a-3) supplying a nitriding gas to the substrate; and
(b) oxidizing the nitride film formed in (a) and modifying the nitride film into an oxide film containing the predetermined element by supplying an oxidizing gas to the substrate.

21. A non-transitory computer-readable recording medium storing a program that causes, by a computer, a substrate processing apparatus to perform a process in a process chamber of the substrate processing apparatus, the process comprising:
(a) forming a nitride film containing a predetermined element on a substrate by performing a cycle a predetermined number of times, the cycle including sequentially performing:
(a-1) supplying a first precursor gas containing the predetermined element to the substrate;
(a-2) supplying a second precursor gas containing the predetermined element and having a thermal decomposition temperature lower than a thermal decomposition temperature of the first precursor gas to the substrate; and
(a-3) supplying a nitriding gas to the substrate; and
(b) oxidizing the nitride film formed in (a) and modifying the nitride film into an oxide film containing the predetermined element by supplying an oxidizing gas to the substrate.

22. A substrate processing apparatus, comprising:
a process chamber in which a substrate is processed;
a first precursor gas supply system configured to supply a first precursor gas containing a predetermined element to the substrate in the process chamber;
a second precursor gas supply system configured to supply a second precursor gas containing the predetermined element and having a thermal decomposition temperature lower than a thermal decomposition temperature of the first precursor gas to the substrate in the process chamber;
a nitriding gas supply system configured to supply a nitriding gas to the substrate in the process chamber;
an oxidizing gas supply system configured to supply an oxidizing gas to the substrate in the process chamber; and
a controller configured to be capable of controlling the first precursor gas supply system, the second precursor gas supply system, the nitriding gas supply system, and the oxidizing gas supply system so as to perform the method of claim 1 in the process chamber.
